(19) United States
(12) Patent Application Publication
(10) Pub. No.: US 2023/0413492 A1
(43) Pub. Date: Dec. 21, 2023

(54) COOLING DISPENSING UNIT FOR DATA CENTER AND DATA CENTER MACHINE ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN); Tao LIU, Zhangjiakou City (CN)

(21) Appl. No.: 18/211,604

(22) Filed: Jun. 20, 2023

(30) Foreign Application Priority Data
Jun. 21, 2022 (CN) 202210706100.0

(51) Int. Cl. H05K 7/20

(52) U.S. Cl. CPC H05K 7/20781; H05K 7/20272

(57) ABSTRACT

Embodiments of the present disclosure provide a cooling dispensing unit for a data center and a data center machine room, belonging to the field of liquid cooling technology. The cooling dispensing unit for the data center includes an outer box and components in the outer box, where the components in the outer box include a heat exchange component, a first cooling liquid pipeline, a second cooling liquid pipeline, and a canned motor pump. The heat exchange component is connected to a tank of the data center through the first cooling liquid pipeline and is connected to an external refrigeration device through the second cooling liquid pipeline. The canned motor pump is installed on the first cooling liquid pipeline and is configured to convey the cooling liquid in the first cooling liquid pipeline.

### CROSS-REFERENCE TO RELATED APPLICATION

This application claims priority to Chinese Patent Application No. 202210706100.0, titled “COOLING DISPENSING UNIT FOR DATA CENTER AND DATA CENTER MACHINE ROOM” and filed to the China National Intellectual Property Administration on Jun. 21, 2022, the entire contents of which are incorporated herein by reference.

### TECHNICAL FIELD

The present disclosure relates to the field of liquid cooling technology, and more particularly, to a cooling dispensing unit for a data center and a data center machine room.

### BACKGROUND

In the era of big data explosion, especially with the development of Artificial Intelligence (AI) technologies, data size grows geometrically. Data centers for operation and storage of the data present a development trend of high density and high power. According to researches made by relevant institutions, energy efficiency of 85% of the data centers in China ranges between 1.5 and 2.0. It is estimated that by 2030, energy consumption of the data centers in China will increase from 160.9 billion KWH in 2018 to 411.5 billion KWH. One of problems brought by such development is how to dissipate heat for the data centers. Traditional air-cooled and water-cooled air conditioners are gradually overwhelmed, while liquid cooling technology has emerged because of its higher efficiency and lower energy consumption.

For a large data center taking a graphics processing unit (GPU) as its core and conforming to AI computing power, the power consumption of a single GPU may reach up to 300 watts, which leads to a serious heat dissipation problem for a whole server. Heat dissipation modes such as cold plate liquid cooling or spray liquid cooling are difficult to meet requirements in efficiency. In this case, a full immersion liquid cooling technology may be relied on to solve the problem of heat dissipation of the server. Belonging to direct contact liquid cooling, the immersion liquid cooling is characterized in that an IT (Internet Technology) device such as the server that needs heat dissipation is completely immersed in a cooling liquid with a high specific heat capacity, which is used as a transmission medium to circulate and take away heat. The cooling liquid in the full immersion liquid cooling is in full contact with the IT device that needs heat dissipation, so the heat dissipation efficiency is higher. In addition, no fan is required, so noise and energy consumption are lower than those of other liquid cooling methods.

By studying the immersion liquid cooling technology of a data center, an inventor of this patent application makes the following findings.

As modular products, existing immersion liquid cooling devices are large in volume and heavy in weight, and are demanding for buildings. The immersion liquid cooling devices are in split layout, where tanks are arranged inside machine rooms, while cooling dispensing units are arranged outside the machine rooms. This cut-up arrangement mode is not conducive to device maintenance, because multi-person cooperation is needed for maintenance operation. Distributed devices cannot reasonably control refrigeration of each batch of servers, and need to be shut down when repairing or replacing the devices, which is lower in efficiency and has a negative effect on normal operation of the servers.

### SUMMARY

To solve some or all problems existing in the prior art, embodiments of the present disclosure provide a cooling dispensing unit for a data center and a data center machine room. The technical solutions are as follows.

In a first aspect, a cooling dispensing unit for a data center is provided, which includes an outer box and components in the outer box, where the components in the outer box include a heat exchange component, a first cooling liquid pipeline, a second cooling liquid pipeline, and a canned motor pump.

The heat exchange component is connected to a tank of the data center through the first cooling liquid pipeline and is connected to an external refrigeration device through the second cooling liquid pipeline, such that a cooling liquid in the first cooling liquid pipeline exchanges heat in the heat exchange component with a cooling liquid in the second cooling liquid pipeline.

The canned motor pump is installed on the first cooling liquid pipeline and is configured to convey the cooling liquid in the first cooling liquid pipeline.

Alternatively, the first cooling liquid pipeline includes a first cooling liquid inlet pipeline and a first cooling liquid outlet pipeline, where the first cooling liquid inlet pipeline includes a pump inlet pipeline and a pump outlet pipeline.

A first end of the pump inlet pipeline is connected to an inlet of the canned motor pump through a flange plate, and a second end of the pump inlet pipeline is connected to the tank through the flange plate.

A first end of the pump outlet pipeline is connected to a first upper interface of the heat exchange component, and a second end of the pump outlet pipeline is connected to an outlet of the canned motor pump through the flange plate.

A first end of the first cooling liquid outlet pipeline is connected to a first lower interface of the heat exchange component, and a second end of the first cooling liquid outlet pipeline is connected to the tank through the flange plate.

Alternatively, a brass thread stop valve and a male-quick coupling are arranged at a lowest point of the pump inlet pipeline, at a lowest point of the pump outlet pipeline, and at a lowest point of the first cooling liquid outlet pipeline.

A pressure transmitter with a stop valve is arranged on the pump inlet pipeline, on the pump outlet pipeline, and on the first cooling liquid outlet pipeline.

A temperature sensor is arranged on the pump inlet pipeline and the first cooling liquid outlet pipeline.

An automatic exhaust valve is arranged at a highest point of the pump outlet pipeline.

A middle of the first cooling liquid outlet pipeline is provided with a quick-fit flowmeter and a right-angle filter, and a tail of the first cooling liquid outlet pipeline is provided with a conductivity meter probe.

Alternatively, a manual butterfly valve is welded into the pump inlet pipeline.

A check valve is welded on the first end of the pump outlet pipeline, and the manual butterfly valve is welded on the second end of the pump outlet pipeline.

The manual butterfly valve is welded on the first end of the first cooling liquid outlet pipeline.

Alternatively, the second cooling liquid pipeline includes a second cooling liquid inlet pipeline and a second cooling liquid outlet pipeline.

A first end of the second cooling liquid inlet pipeline is connected to a second lower interface of the heat exchange device, and a second end of the second cooling liquid inlet pipeline is connected to the external refrigeration device through the flange plate.

A first end of the second cooling liquid outlet pipeline is connected to a second upper interface of the heat exchange component, and a second end of the second cooling liquid outlet pipeline is connected to the external refrigeration device through the flange plate.

Alternatively, a brass thread stop valve and a male-quick coupling are arranged at a lowest point of the second cooling liquid inlet pipeline.

A pressure transmitter with a stop valve and a temperature sensor are arranged on the second cooling liquid inlet pipeline and the second cooling liquid outlet pipeline.

A middle of the second cooling liquid inlet pipeline is provided with a quick-fit electric valve.

An automatic exhaust valve is installed at a highest point of the second cooling liquid outlet pipeline.

Alternatively, a manual butterfly valve is welded to the first end of the second cooling liquid inlet pipeline and the first end of the second cooling liquid outlet pipeline.

Alternatively, the components in the outer box also include an electric control box, a frequency converter, a conductivity meter controller, and a touch screen.

The electric control box, the frequency converter, the conductivity meter controller, the heat exchange component and the canned motor pump are hoisted and fixed to a bracket of the outer box through bolted connection.

An operation interface of the electric control box and an operation interface of the frequency converter both face a front gate of the electric control box, and the conductivity meter controller faces a rear gate of the electric control box.

The touch screen is installed at a top of the outer box.

Alternatively, the components in the outer box further include a pipeline bracket, the pipeline bracket is installed on the first cooling liquid pipeline and the second cooling liquid pipeline and is connected to a bracket of the outer box, and the pipeline bracket is configured to fix the first cooling liquid pipeline and the second cooling liquid pipeline.

Alternatively, the outer box is not higher than 1,200 mm, not longer than 600 mm, and not wider than 800 mm.

In a second aspect, a data center machine room is provided, which includes at least one set of cooling dispensing unit for the data center as described above, where each set of the cooling dispensing unit for the data center includes at least two cooling dispensing units for the data centers to implement operation of double pump mode or single pump mode.

The technical solutions provided by the embodiments of the present disclosure have following beneficial effects.

A first cooling liquid exchanges heat with a second cooling liquid in the heat exchange component through two circulation loops, which can effectively reduce a temperature of the first cooling liquid, thereby cooling a server, ensuring quality requirements for the server and meeting accurate control of the temperature of the server. The cooling dispensing unit for the data center is small in size, which reduces consumption of building resources and human resources. At least two cooling dispensing units for the data centers are deployed in the data center machine room, and the at least two cooling dispensing units for the data centers can be operated in double pump mode or single pump mode, and thus can be maintained without shutdown.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a front view of a cooling dispensing unit for a data center according to an embodiment of the present disclosure;

FIG. 2 is a left view of the cooling dispensing unit for the data center shown in FIG. 1;

FIG. 3 is a rear view of the cooling dispensing unit for the data center shown in FIG. 1;

FIG. 4 is a right view of the cooling dispensing unit for the data center shown in FIG. 1;

FIG. 5 is a vertical view of the cooling dispensing unit for the data center shown in FIG. 1;

FIG. 6 is a perspective view of the cooling dispensing unit for the data center shown in FIG. 1; and

FIG. 7 is a schematic structural diagram of a data center machine room according to an embodiment provided by the present disclosure.

Reference numerals in the accompanying drawings:

outer box 1, heat exchange component 2, canned motor pump 3, electric control box 4, touch screen 5, frequency converter 6, conductivity meter controller 7, conductivity meter probe 8, quick-fit flowmeter 9, right-angle filter 10, pump inlet pipeline 11, pump outlet pipeline 12, first cooling liquid outlet pipeline 13, second cooling liquid inlet pipeline 14, second cooling liquid outlet pipeline 15, quick-fit electric valve 16, brass thread stop valve 17, pressure transmitter 18 with stop valve, temperature sensor 19, automatic exhaust valve 20, male-quick coupling 21, and pipeline bracket 22.

### DETAILED DESCRIPTION

To make the objectives, technical solutions and advantages of the present disclosure clearer, the embodiments of the present disclosure will be further described below in detail with reference to the accompanying drawings. Terms such as “upper”, “above”, “lower”, “below”, “first end”, “second end”, “one end”, “other end” and the like as used herein, which denote spatial relative positions, describe the relationship of one unit or feature relative to another unit or feature in the accompanying drawings for the purpose of illustration. The terms of the spatial relative positions may be intended to include different orientations of the device in use or operation other than the orientations shown in the accompanying drawings. For example, the units that are described as “below” or “under” other units or features will be “above” other units or features if the device in the accompanying drawings is turned upside down. Thus, the exemplary term “below” can encompass both the orientations of above and below. The device may be otherwise oriented (rotated by 90 degrees or facing other directions) and the space-related descriptors used herein are interpreted accordingly.

In addition, the terms “installed”, “arranged”, “provided”, “connected”, “sliding connection”, “fixed” and “socket” should be understood broadly. For example, the “connection” may be a fixed connection, a detachable connection or integrated connection, a mechanical connection or an electrical connection, a direct connection or indirect connection by means of an intermediary, or an internal connection between two apparatuses, components or constituent parts. For those of ordinary skill in the art, concrete meanings of the above terms in the present disclosure may be understood based on concrete circumstances.

The embodiments of the present disclosure provide a cooling dispensing unit (CDU) for a data center. The CDU includes an outer box and components in the outer box, where the components in the outer box include a heat exchange component, a first cooling liquid pipeline, a second cooling liquid pipeline, and a canned motor pump. The heat exchange component is connected to a tank of the data center through the first cooling liquid pipeline and is connected to an external refrigeration device through the second cooling liquid pipeline, such that a cooling liquid in the first cooling liquid pipeline exchanges heat in the heat exchange component with a cooling liquid in the second cooling liquid pipeline. The canned motor pump is installed on the first cooling liquid pipeline and is configured to convey the cooling liquid in the first cooling liquid pipeline.

In implementation, the heat exchange component may be a plate heat exchanger, and the cooling liquid may flow in a flow passage of the plate heat exchanger to exchange heat through plates. The tank is an immersion box where a server is placed.

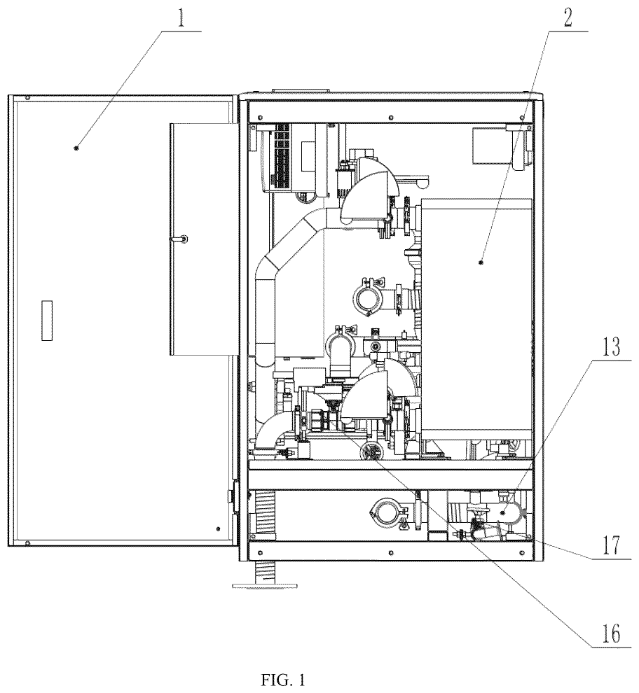

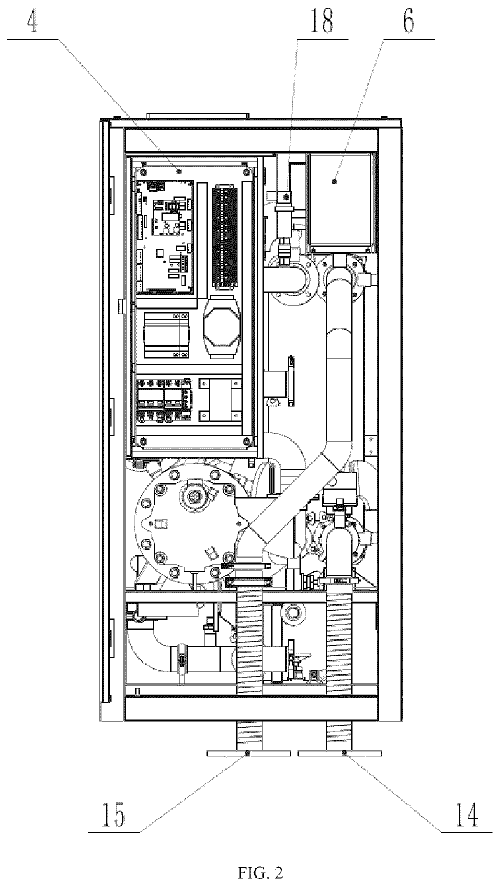

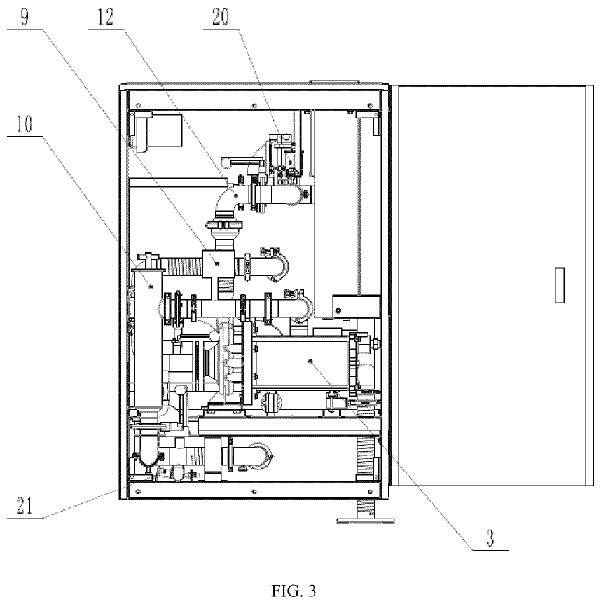

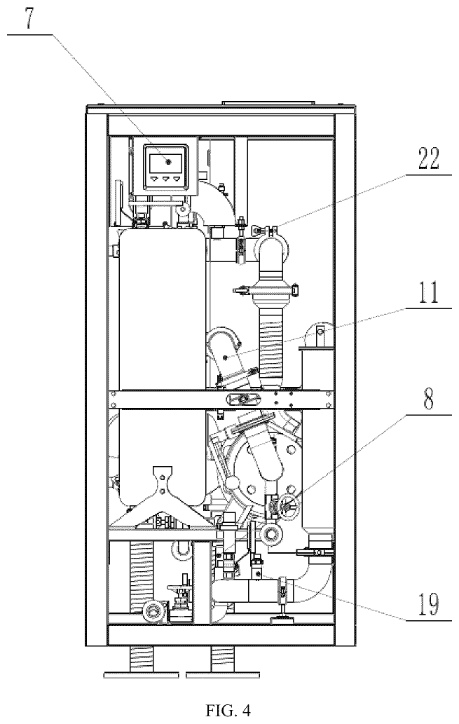

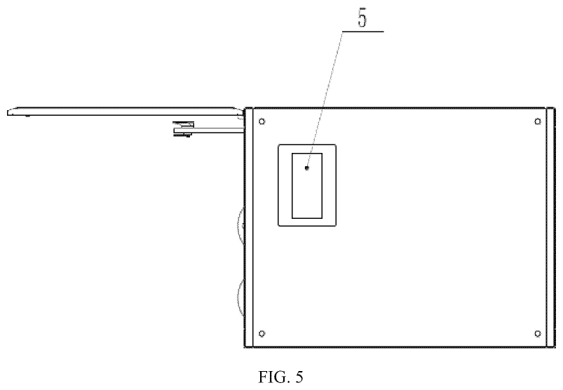

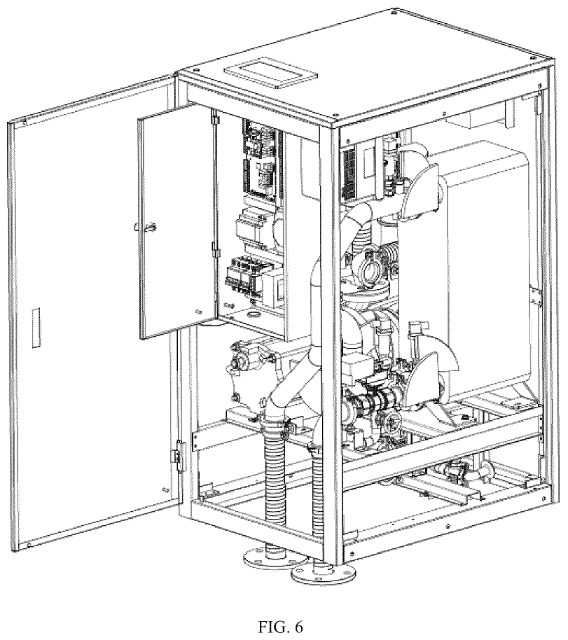

The cooling dispensing unit for the data center shown in FIGS. 1 to 6 will be described in detail below with reference to specific embodiments.

In one embodiment, the first cooling liquid pipeline includes a first cooling liquid inlet pipeline and a first cooling liquid outlet pipeline, where the first cooling liquid inlet pipeline includes a pump inlet pipeline and a pump outlet pipeline. A first end of the pump inlet pipeline is connected to an inlet of the canned motor pump through a flange plate, and a second end of the pump inlet pipeline is connected to the tank through the flange plate. A first end of the pump outlet pipeline is connected to a first upper interface of the heat exchange component, and a second end of the pump outlet pipeline is connected to an outlet of the canned motor pump through the flange plate. A first end of the first cooling liquid outlet pipeline is connected to a first lower interface of the heat exchange component, and a second end of the first cooling liquid outlet pipeline is connected to the tank through the flange plate.

In implementation, a first cooling liquid (e.g. fluorinated liquid) from the tank is sucked into a pump by a canned motor pump 3 through a pump inlet pipeline 11, then is discharged into a plate heat exchanger 2 through a pump outlet pipeline, and is discharged to the tank through a first cooling liquid outlet pipeline 13 for circulation. A right-angle filter 10 and a conductivity meter probe 8 arranged in the first cooling liquid outlet pipeline can effectively filter and monitor impurities in the circulation process of the fluorinated liquid. A second cooling liquid (e.g. ethylene glycol) from an external refrigeration device enters the plate heat exchanger 2 through a second cooling liquid inlet pipeline 14 under the action of an external pressure and is discharged through a second cooling liquid outlet pipeline 15 for circulation. Such a two-way circulation loop carries out heat exchange operation in the plate heat exchanger 2, which can effectively reduce a temperature of the fluorinated liquid and cool the server. Data monitored by a quick-fit flowmeter 9, by a pressure transmitter 18 with a stop valve, and by a temperature sensor 19 are transmitted to an electric control box 4 through a circuit, and then input of a frequency converter 6 is adjusted through operation of a touch screen 5 to control an operating state of the canned motor pump 3. An automatic exhaust valve 20 may automatically exhaust air in the circulating liquid. When a device needs maintenance, a brass thread stop valve 17 may be employed to discharge the liquid in the pipeline to a liquid replenishing vehicle or a container.

It is worth mentioning that the cooling liquid in the first cooling liquid pipeline comes from the tank, and brings heat out of the server, and thus has a higher temperature. The cooling liquid in the second cooling liquid pipeline comes from an external refrigeration device to exchange heat with the first cooling liquid, and thus has a lower temperature. Therefore, the temperature of the cooling liquid in the first cooling liquid pipeline entering the heat exchange component is higher than that of the cooling liquid in the second cooling liquid pipeline entering the heat exchange component. In an embodiment, the fluorinated liquid from the tank has a higher temperature when entering the plate heat exchanger, and thus may be referred to as a high-temperature fluorinated liquid. The ethylene glycol solution from the external refrigeration device has a lower temperature when entering the plate heat exchanger, and thus may be referred to as a low-temperature ethylene glycol liquid.

In one embodiment, a brass thread stop valve and a male-quick coupling are arranged at a lowest point of the pump inlet pipeline 11, at a lowest point of the pump outlet pipeline 12, and at a lowest point of the first cooling liquid outlet pipeline 13. A pressure transmitter with a stop valve is arranged on the pump inlet pipeline 11, on the pump outlet pipeline 12, and on the first cooling liquid outlet pipeline 13. A temperature sensor is arranged on the pump inlet pipeline 11 and the first cooling liquid outlet pipeline 13. An automatic exhaust valve is arranged at a highest point of the pump outlet pipeline 12. A middle of the first cooling liquid outlet pipeline 13 is provided with a quick-fit flowmeter and a right-angle filter, and a tail of the first cooling liquid outlet pipeline 13 is provided with a conductivity meter probe.

In one embodiment, a manual butterfly valve is welded into the pump inlet pipeline 11. A check valve is welded on the first end of the pump outlet pipeline 12, and the manual butterfly valve is welded on the second end of the pump outlet pipeline 12. The manual butterfly valve is welded on the first end of the first cooling liquid outlet pipeline 13.

In implementation, the first end of the first cooling liquid outlet pipeline is an end adjacent to the plate heat exchanger.

In one embodiment, the second cooling liquid pipeline includes a second cooling liquid inlet pipeline 14 and a second cooling liquid outlet pipeline 15. A first end of the second cooling liquid inlet pipeline 14 is connected to a second lower interface of the heat exchange device, and a second end of the second cooling liquid inlet pipeline 14 is connected to the external refrigeration device through the flange plate. A first end of the second cooling liquid outlet pipeline 15 is connected to a second upper interface of the heat exchange component, and a second end of the second cooling liquid outlet pipeline 15 is connected to the external refrigeration device through the flange plate.

In one embodiment, a brass thread stop valve and a male-quick coupling are arranged at a lowest point of the second cooling liquid inlet pipeline 14. A pressure transmitter with a stop valve and a temperature sensor are arranged on the second cooling liquid inlet pipeline 14 and the second cooling liquid outlet pipeline 15. A middle of the second cooling liquid inlet pipeline 14 is provided with a quick-fit electric valve. An automatic exhaust valve is installed at a highest point of the second cooling liquid outlet pipeline 15.

In one embodiment, a manual butterfly valve is welded to the first end of the second cooling liquid inlet pipeline 14 and the first end of the second cooling liquid outlet pipeline 15.

In implementation, the first end of the second cooling liquid inlet pipeline is an end adjacent to the plate heat exchanger.

In one embodiment, the components in the outer box further include an electric control box 4, a frequency converter 6, a conductivity meter controller 7, and a touch screen 5. The electric control box 4, the frequency converter 6, the conductivity meter controller 7, the heat exchange component 2 and the canned motor pump 3 are hoisted and fixed to a bracket of the outer box through bolted connection. An operation interface of the electric control box 4 and an operation interface of the frequency converter 6 both face a front gate of the electric control box, and the conductivity meter controller 7 faces a rear gate of the electric control box. The touch screen 5 is installed at a top of the outer box.

In one embodiment, the components in the outer box further include a pipeline bracket 22, the pipeline bracket is installed on the first cooling liquid pipeline and the second cooling liquid pipeline and is connected to a bracket of the outer box, and the pipeline bracket is configured to fix the first cooling liquid pipeline and the second cooling liquid pipeline.

In implementation, the pipeline bracket 22 may be a DGA pipeline bracket, which is arranged on each pipeline and connected to the bracket on the outer box 1 for fixing.

In one embodiment, the outer box is not higher than 1,200 mm, not longer than 600 mm, and not wider than 800 mm.

In implementation, by adopting the above apparatus structure, internal layout of the cooling dispensing unit for the data center can be ensured to be compact and reasonable, and the volume can be reduced. A frame of the cooling dispensing unit for the data center of the present disclosure has a maximum height of 1,200 mm, a maximum length of 600 mm and a maximum width of 800 mm. For example, a size of the cooling dispensing unit for the data center may be 1,200 mm high, 600 mm long and 800 mm wide; 1,000 mm high, 500 mm long and 700 mm wide; or 900 mm high, 400 mm long and 500 mm wide, etc.

Based on the same technical idea, the embodiments of the present disclosure also provide a data center machine room, which includes at least one set of cooling dispensing unit for the data center as described above, where each set of the cooling dispensing unit for the data center includes at least two cooling dispensing units for the data centers to implement operation of double pump mode or single pump mode.

The double pump mode may be understood as simultaneous operation of two cooling dispensing units for the data centers to dissipate heat from the server in the data center. The single pump mode may be understood as separate operation of one cooling dispensing unit for the data center.

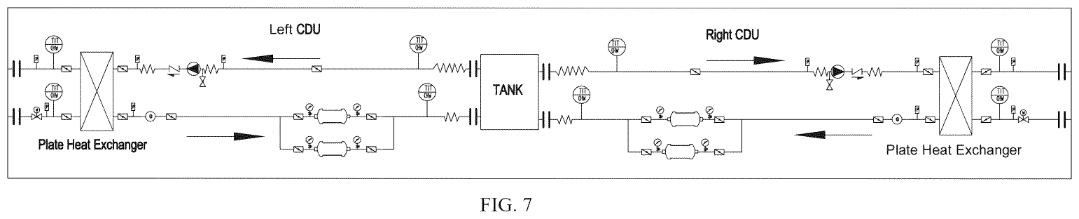

Referring to FIG. 7, in one embodiment, the data center machine room includes two cooling dispensing units for the data centers. For ease of description, the cooling dispensing unit for the data center on the left side of the figure may be referred to as a left CDU, and the cooling dispensing unit for the data center on the right side may be referred to as a right CDU. Based on such arrangement, for any cooling dispensing unit for the data center in the double pump mode, the high-temperature fluorinated liquid from the tank is sucked into the pump by the canned motor pump 3 through the pump inlet pipeline 11, then is discharged into the plate heat exchanger 2 through the pump outlet pipeline, and is discharged to the tank through a fluorinated liquid outlet pipeline 13 for circulation. The right-angle filter 10 and the conductivity meter probe 8 arranged in the fluorinated liquid outlet pipeline can effectively filter and monitor the impurities in the circulation process of the fluorinated liquid. The low-temperature ethylene glycol liquid from the external refrigeration device enters the plate heat exchanger 2 through an ethylene glycol inlet pipeline 14 under the action of an external pressure, and is discharged through an ethylene glycol outlet pipeline 15 for circulation. Such a two-way circulation loop carries out heat exchange operation in the plate heat exchanger, which can effectively reduce the temperature of the fluorinated liquid and cool the server. Data monitored by the quick-fit flowmeter 9, by the pressure transmitter 18 with the stop valve, and by the temperature sensor 19 are transmitted to the electric control box 4 through the circuit, and then input of the frequency converter 6 is adjusted through operation of the touch screen 5 to control the operating state of the canned motor pump 3. The automatic exhaust valve 20 may automatically exhaust air in the circulating liquid. When the device needs maintenance, the cooling dispensing unit for the data center may be converted into the single pump mode. For the cooling dispensing unit for the data center that stops operating, the brass thread stop valve 17 is employed to discharge the liquid in the pipeline to the liquid replenishing vehicle or the container. In this case, the cooling dispensing unit for the data center operating in the single pump mode can continue dissipating heat from the server without interruption.

By adopting the cooling dispensing unit for the data center, the present disclosure can produce the following technical effects.

The first cooling liquid exchanges heat with the second cooling liquid in the heat exchange component through two circulation loops, which can effectively reduce the temperature of the first cooling liquid, thereby cooling the server, ensuring quality requirements for the server and meeting accurate control of the temperature of the server. The cooling dispensing unit for the data center is small in size, which reduces consumption of building resources and human resources. At least two cooling dispensing units for the data centers are deployed in the data center machine room, and the at least two cooling dispensing units for the data centers can be operated in the double pump mode or the single pump mode, and thus can be maintained without shutdown.

The embodiments described above are only illustrated as preferred embodiments of the present disclosure, and are not intended to limit the present disclosure.

All modifications, equivalent substitutions and improvements made within the spirit and principles of the present disclosure shall fall within the protection scope of the present disclosure.

What is claimed is:

1. A cooling dispensing unit for a data center, comprising an outer box and components in the outer box, the components in the outer box comprising a heat exchange component, a first cooling liquid pipeline, a second cooling liquid pipeline and a canned motor pump, wherein
the heat exchange component is connected to a tank of the data center through the first cooling liquid pipeline and is connected to an external refrigeration device through the second cooling liquid pipeline, such that a cooling liquid in the first cooling liquid pipeline exchanges heat in the heat exchange component with a cooling liquid in the second cooling liquid pipeline; and
the canned motor pump is installed on the first cooling liquid pipeline and is configured to convey the cooling liquid in the first cooling liquid pipeline.

2. The cooling dispensing unit for the data center according to claim 1, wherein the first cooling liquid pipeline comprises a first cooling liquid inlet pipeline and a first cooling liquid outlet pipeline, and the first cooling liquid inlet pipeline comprises a pump inlet pipeline and a pump outlet pipeline;
a first end of the pump inlet pipeline is connected to an inlet of the canned motor pump through a flange plate, and a second end of the pump inlet pipeline is connected to the tank through the flange plate;
a first end of the pump outlet pipeline is connected to a first upper interface of the heat exchange component, and a second end of the pump outlet pipeline is connected to an outlet of the canned motor pump through the flange plate; and
a first end of the first cooling liquid outlet pipeline is connected to a first lower interface of the heat exchange component, and a second end of the first cooling liquid outlet pipeline is connected to the tank through the flange plate.

3. The cooling dispensing unit for the data center according to claim 2, wherein:
a brass thread stop valve and a male-quick coupling are arranged at a lowest point of the pump inlet pipeline, at a lowest point of the pump outlet pipeline, and at a lowest point of the first cooling liquid outlet pipeline;
a pressure transmitter with a stop valve is arranged on the pump inlet pipeline, on the pump outlet pipeline, and on the first cooling liquid outlet pipeline;
a temperature sensor is arranged on the pump inlet pipeline and the first cooling liquid outlet pipeline;
an automatic exhaust valve is arranged at a highest point of the pump outlet pipeline; and
a middle of the first cooling liquid outlet pipeline is provided with a quick-fit flowmeter and a right-angle filter, and a tail of the first cooling liquid outlet pipeline is provided with a conductivity meter probe.

4. The cooling dispensing unit for the data center according to claim 2, wherein:
a manual butterfly valve is welded into the pump inlet pipeline;
a check valve is welded on the first end of the pump outlet pipeline, and the manual butterfly valve is welded on the second end of the pump outlet pipeline; and
the manual butterfly valve is welded on the first end of the first cooling liquid outlet pipeline.

5. The cooling dispensing unit for the data center according to claim 1, wherein the second cooling liquid pipeline comprises a second cooling liquid inlet pipeline and a second cooling liquid outlet pipeline;
a first end of the second cooling liquid inlet pipeline is connected to a second lower interface of the heat exchange device, and a second end of the second cooling liquid inlet pipeline is connected to the external refrigeration device through a flange plate; and
a first end of the second cooling liquid outlet pipeline is connected to a second upper interface of the heat exchange component, and a second end of the second cooling liquid outlet pipeline is connected to the external refrigeration device through the flange plate.

6. The cooling dispensing unit for the data center according to claim 5, wherein:
a brass thread stop valve and a male-quick coupling are arranged at a lowest point of the second cooling liquid inlet pipeline;
a pressure transmitter with a stop valve and a temperature sensor are arranged on the second cooling liquid inlet pipeline and the second cooling liquid outlet pipeline;
a middle of the second cooling liquid inlet pipeline is provided with a quick-fit electric valve; and
an automatic exhaust valve is installed at a highest point of the second cooling liquid outlet pipeline.

7. The cooling dispensing unit for the data center according to claim 5, wherein:
a manual butterfly valve is welded to the first end of the second cooling liquid inlet pipeline and the first end of the second cooling liquid outlet pipeline.

8. The cooling dispensing unit for the data center according to claim 1, wherein the components in the outer box further comprise an electric control box, a frequency converter, a conductivity meter controller, and a touch screen;
the electric control box, the frequency converter, the conductivity meter controller, the heat exchange component and the canned motor pump are hoisted and fixed to a bracket of the outer box through bolted connection;
an operation interface of the electric control box and an operation interface of the frequency converter both face a front gate of the electric control box, and the conductivity meter controller faces a rear gate of the electric control box; and
the touch screen is installed at a top of the outer box.

9. The cooling dispensing unit for the data center according to claim 1, wherein the components in the outer box further comprise a pipeline bracket, the pipeline bracket being installed on the first cooling liquid pipeline and the second cooling liquid pipeline and being connected to a bracket of the outer box, and the pipeline bracket being configured to fix the first cooling liquid pipeline and the second cooling liquid pipeline.

10. The cooling dispensing unit for the data center according to claim 1, wherein the outer box is not higher than 1,200 mm, not longer than 600 mm, and not wider than 800 mm.

11. A data center machine room comprising at least one set of cooling dispensing unit for the data center, wherein the cooling dispensing unit comprises an outer box and components in the outer box, the components in the outer box comprising a heat exchange component, a first cooling liquid pipeline, a second cooling liquid pipeline and a canned motor pump, wherein
the heat exchange component is connected to a tank of the data center through the first cooling liquid pipeline and is connected to an external refrigeration device through the second cooling liquid pipeline, such that a cooling liquid in the first cooling liquid pipeline exchanges heat in the heat exchange component with a cooling liquid in the second cooling liquid pipeline; and
the canned motor pump is installed on the first cooling liquid pipeline and is configured to convey the cooling liquid in the first cooling liquid pipeline;
wherein each set of the cooling dispensing unit for the data center comprises at least two of the cooling dispensing units for the data centers to implement operation of double pump mode or single pump mode.

12. The data center machine room according to claim 11, wherein the first cooling liquid pipeline comprises a first cooling liquid inlet pipeline and a first cooling liquid outlet pipeline, and the first cooling liquid inlet pipeline comprises a pump inlet pipeline and a pump outlet pipeline;
a first end of the pump inlet pipeline is connected to an inlet of the canned motor pump through a flange plate, and a second end of the pump inlet pipeline is connected to the tank through the flange plate;
a first end of the pump outlet pipeline is connected to a first upper interface of the heat exchange component, and a second end of the pump outlet pipeline is connected to an outlet of the canned motor pump through the flange plate; and
a first end of the first cooling liquid outlet pipeline is connected to a first lower interface of the heat exchange component, and a second end of the first cooling liquid outlet pipeline is connected to the tank through the flange plate.

13. The data center machine room according to claim 12, wherein:
a brass thread stop valve and a male-quick coupling are arranged at a lowest point of the pump inlet pipeline, at a lowest point of the pump outlet pipeline, and at a lowest point of the first cooling liquid outlet pipeline;
a pressure transmitter with a stop valve is arranged on the pump inlet pipeline, on the pump outlet pipeline, and on the first cooling liquid outlet pipeline;
a temperature sensor is arranged on the pump inlet pipeline and the first cooling liquid outlet pipeline;
an automatic exhaust valve is arranged at a highest point of the pump outlet pipeline; and
a middle of the first cooling liquid outlet pipeline is provided with a quick-fit flowmeter and a right-angle filter, and a tail of the first cooling liquid outlet pipeline is provided with a conductivity meter probe.

14. The data center machine room according to claim 12, wherein:
a manual butterfly valve is welded into the pump inlet pipeline;
a check valve is welded on the first end of the pump outlet pipeline, and the manual butterfly valve is welded on the second end of the pump outlet pipeline; and
the manual butterfly valve is welded on the first end of the first cooling liquid outlet pipeline.

15. The data center machine room according to claim 11, wherein the second cooling liquid pipeline comprises a second cooling liquid inlet pipeline and a second cooling liquid outlet pipeline;
a first end of the second cooling liquid inlet pipeline is connected to a second lower interface of the heat exchange device, and a second end of the second cooling liquid inlet pipeline is connected to the external refrigeration device through a flange plate; and
a first end of the second cooling liquid outlet pipeline is connected to a second upper interface of the heat exchange component, and a second end of the second cooling liquid outlet pipeline is connected to the external refrigeration device through the flange plate.

16. The data center machine room according to claim 15, wherein:
a brass thread stop valve and a male-quick coupling are arranged at a lowest point of the second cooling liquid inlet pipeline;
a pressure transmitter with a stop valve and a temperature sensor are arranged on the second cooling liquid inlet pipeline and the second cooling liquid outlet pipeline;
a middle of the second cooling liquid inlet pipeline is provided with a quick-fit electric valve; and
an automatic exhaust valve is installed at a highest point of the second cooling liquid outlet pipeline.

17. The data center machine room according to claim 15, wherein:
a manual butterfly valve is welded to the first end of the second cooling liquid inlet pipeline and the first end of the second cooling liquid outlet pipeline.

18. The data center machine room according to claim 11, wherein the components in the outer box further comprise an electric control box, a frequency converter, a conductivity meter controller, and a touch screen;
the electric control box, the frequency converter, the conductivity meter controller, the heat exchange component and the canned motor pump are hoisted and fixed to a bracket of the outer box through bolted connection;
an operation interface of the electric control box and an operation interface of the frequency converter both face a front gate of the electric control box, and the conductivity meter controller faces a rear gate of the electric control box; and
the touch screen is installed at a top of the outer box.

19. The data center machine room according to claim 11, wherein the components in the outer box further comprise a pipeline bracket, the pipeline bracket being installed on the first cooling liquid pipeline and the second cooling liquid pipeline and being connected to a bracket of the outer box, and the pipeline bracket being configured to fix the first cooling liquid pipeline and the second cooling liquid pipeline.

20. The data center machine room according to claim 11, wherein the outer box is not higher than 1,200 mm, not longer than 600 mm, and not wider than 800 mm.
